(19) United States
(12) Patent Application Publication
(10) Pub. No.: US 2025/0167025 A1
(43) Pub. Date: May 22, 2025

(54) APPARATUS AND METHODS FOR REDUCING WAFER BACKSIDE DAMAGE

(71) Applicant: Lam Research Corporation, Fremont, CA (US)

(72) Inventors: Sairam Sundaram, Wilsonville, OR (US); Ramesh Chandrasekharan, Lake Oswego, OR (US); Christopher Gage, Truckee, CA (US)

(73) Assignee: Lam Research Corporation, Fremont, CA (US)

(21) Appl. No.: 18/840,339

(22) PCT Filed: Feb. 24, 2023
(86) PCT No.: PCT/US2023/063240

§ 371 Date: Aug. 21, 2024

Related U.S. Application Data
(60) Provisional application No. 63/269,607, filed on Mar. 18, 2022.

(51) Int. Cl. H01L 21/67; H01L 21/683; H01L 21/687

(52) U.S. Cl. CPC H01L 21/67288; H01L 21/6833; H01L 21/6838; H01L 21/6875

(57) ABSTRACT

A wafer chuck assembly is disclosed, in accordance with at least one embodiment. In at least one embodiment, wafer chuck assembly comprises a wafer chuck comprising a substantially circular surface having a first area. In least one embodiment, plurality of mesas is distributed over the wafer chuck surface. In at least one embodiment, individual ones of the plurality of mesas extend a height above the wafer chuck surface. In at least one embodiment, plurality of mesas has a contact surface having a second area that is at least 3% of the first area.

### CLAIM FOR PRIORITY

This application is a continuation of and claims benefit of priority to U.S. Patent Application No. 63/269,607, filed on Mar. 18, 2022, titled “APPARATUS AND METHODS FOR REDUCING WAFER BACKSIDE DAMAGE,” and which is incorporated by reference in its entirety.

### BACKGROUND

Substrate processing tools are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. During deposition, wafer substrate is clamped down on a substrate support (e.g., a pedestal). The pedestal may hold the substrate by electrostatic clamping or by vacuum clamping facilitated by a chuck on the pedestal. In either mode, the wafer substrate is pressed against the chuck. In many processes, the wafer is thermally cycled to control deposition or etching chemistry on the exposed surface of the wafer substrate. Microscopic irregularities on the chuck surface may rub or scrape off small particles from the backside of the wafer substrate during thermal equilibration as the wafer expands or contracts. The particles may accumulate on the chuck, and transfer to subsequent wafer substrates during sequential processing of multiple wafers in the same tool. The contamination of wafer backsides by adventitious particle attachment may affect downstream processing. For example, backside particle contamination may affect quality of subsequent photolithography operations.

A common solution is to incorporate a plurality of contact-minimizing structures on the chuck surface, presenting a minimum contact area to a wafer clamped to the chuck. contact-minimizing structures may be in the form of small hemispherical domes or pillars for example, distributed on the chuck surface. The structures may minimize the contact surface area between the backside of the wafer substrate and the chuck. A wafer mounted on a chuck may rest on the contact-minimizing structures, which may also offset the wafer from the chuck surface. An advantage realized by the vertical offset between the wafer and chuck surface may be the reduction of debris formation, such as generation of large dust particles and microscopic particles of photoresist to be otherwise generated by contact with a flat surface. The number of point contact structures may be few. The total contact area of the structures may be restricted to a small fraction of the wafer area, for example, less than 1%. While minimal contact area may be beneficial to mitigate particle generation, clamping forces may be magnified over the contact-minimizing structures, pressing the structures into the backside surface of the substrate. Often, the structures have a dome shape, presenting a single point of contact to the wafer backside. Clamping pressure may be very high at these contact points. For example, a resist coating or deposited metal or oxide or nitride film present on the wafer backside may be damaged by indentation or cracking metal or dielectric films from the excess pressure due to the very small contact areas of the structures. A solution is needed for reducing damage caused by mesas while maintaining their benefits.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a cross-sectional view of a wafer chuck assembly comprising mesas on a wafer chuck surface, according to at least one embodiment.

FIG. 2 illustrates a plan view of a first embodiment of a wafer chuck assembly comprising hexagonal mesas, according to at least one embodiment.

FIG. 3 illustrates a plan view of a wafer chuck assembly comprising a plurality of round mesas, according to at least one embodiment.

FIG. 4 illustrates a plan view of a wafer chuck assembly comprising a plurality of line mesas, according to at least one embodiment.

FIG. 5 illustrates a plan view of a wafer chuck assembly comprising a plurality of wedge-shaped mesas in a symmetrical angular distribution, according to at least one embodiment.

FIG. 6 illustrates a plan view of a wafer chuck assembly comprising a plurality of mesas in a logarithmically increasing radial distribution, according to at least one embodiment.

FIG. 7 illustrates a plan view of a wafer chuck assembly comprising a plurality of mesas in a logarithmically decreasing radial distribution, according to at least one embodiment.

FIG. 8 illustrates a plan view of a wafer chuck assembly comprising a plurality of mesas which have a logarithmic radial distribution and logarithmic progression of diameter, according to at least one embodiment.

FIG. 9 illustrates a plan view of a wafer chuck assembly comprising a plurality of mesas comprising tiled mesas, according to at least one embodiment.

FIG. 10 illustrates a cross-sectional view of a wafer process apparatus comprising a wafer chuck assembly comprising a plurality of mesas, according to at least one embodiment.

FIG. 11 illustrates a flow chart summarizing an exemplary method for using a wafer process apparatus, according to at least one embodiment.

### DETAILED DESCRIPTION

At least one embodiment describes minimum contact area stand-off patterns for reducing wafer backside damage. Here, numerous specific details are set forth, such as structural schemes, to provide a thorough understanding of at least one embodiment. It will be apparent to one skilled in art that at least one embodiment may be practiced without these specific details. In other instances, well-known features, such as gas line tubing fittings, heating elements and snap switches, are described in lesser detail to not unnecessarily obscure an embodiment. Furthermore, it is to be understood that at least one embodiment shown in figures is illustrative representation and may be not necessarily drawn to scale.

In some instances, well-known methods and devices are shown in block diagram form, rather than in detail, to avoid obscuring present disclosure. Reference throughout this specification to “an embodiment” “at least one embodiment” or “one embodiment” or “some embodiments” means that a particular feature, structure, function, or characteristic described in connection with at least one embodiment may be included in at least one embodiment of disclosure. Thus, appearances of phrase “in an embodiment” or “at least one embodiment” or “in one embodiment” or “some embodiments” in various places throughout this specification are not necessarily referring to a same embodiment. Furthermore, particular features, structures, functions, or characteristics may be combined in any suitable manner in one or more embodiments. For example, a first embodiment may be combined with a second embodiment anywhere particular features, structures, functions, or characteristics associated with two embodiments are not mutually exclusive.

Here, “coupled” and “connected,” along with their derivatives, may be used herein to describe functional or structural relationships between components. These terms are not intended as synonyms for one another. Rather, in particular embodiments, “connected” may be used to indicate that two or more elements are in direct physical, optical, or electrical contact with one another. “Coupled” may be used to indicated that two or more elements are in either direct or indirect (with other intervening elements between them) physical, electrical or in magnetic contact with one another, and/or that two or more elements co-operate or interact with one another (e.g., as in a cause an effect relationship).

Here, “over,” “under,” “between,” and “on” as used herein may generally refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by “at least one of” or “one or more of” can mean any combination of listed terms.

Here, “adjacent” here may generally refer to a position of a thing being next to (e.g., immediately next to or close to with one or more things between them) or adjoining another thing (e.g., abutting it).

Unless otherwise specified in explicit context of their use, terms “substantially equal,” “about equal” and “approximately equal” may generally mean that there may be no more than incidental variation between two things so described. Such variation may be typically no more than +/−10% of referred value.

To address at least limitations described herein, wafer chuck assembly embodiments comprising high-density mesa patterns are disclosed. Here, “mesa” may generally refer to a plurality of contact-minimizing structures such as small mesas on a wafer chuck surface upon which a substrate, such as a semiconductor wafer, may be mounted. In this disclosure, “mesa” may be used throughout as embodiments of mesas. In at least one embodiment, mesa may have a substantially flat contact surface, affording a larger contact area than a point contact of a more conventional hemispherical structure. In at least one embodiment, while individual mesas may afford a very small contact area between wafer and platen, when amassed in high-density patterns, collective contact area may be sufficient to reduce contact pressure due to clamping forces on individual mesas to below a critical level, above which damage backside layers may occur.

In at least one embodiment, threshold contact area may be at least 3% (e.g., between 3% and 90%) of total surface area of wafer chuck assembly to reduce clamping force load per individual mesa. Reduction of clamping force load per individual mesa may decrease wafer backside damage due to excessive load born by individual mesas. In at least one embodiment, mesas comprise rounded or sloped leading edges between sidewalls and top surfaces. In at least one embodiment, rounded leading top and/or side edges may reduce mesa-induced scratching and marring of backside wafer films or layers when wafers expand or contract during thermal cycling. Here, “rounded’ generally refers to top edges of mesas where a top contact surface and sidewalls intersect. In at least one embodiment, rounded edges may be characterized by a radius of curvature instead of a sharp angle. Here, “sloped” in context of mesa top edges generally refers to edges that may have a transition extending at an oblique angle between a substantially vertical sidewall and a substantially horizontal top surface.

Here, “wafer chuck” may generally refer to a structure comprising a plate or platen on which a wafer may be mounted and clamped. In at least one embodiment, clamping of wafer may be effectuated by vacuum clamping or by electrostatic clamping. Here, “vacuum clamping” may generally refer to a means of clamping a wafer substrate to a wafer chuck by vacuum. Here, “electrostatic clamping” may generally refer to a means of clamping a wafer substrate to a wafer chuck by electrostatic force. In at least one embodiment, platen may comprise a surface having a substantially circular geometry. Here, “wafer chuck assembly” may generally refer to an assembly comprising a wafer chuck and may further include a column attached to wafer chuck, where column may house cables, wires, vacuum tubing, and gas lines that are fed to wafer chuck. Here, “wafer chuck surface” may generally refer to a surface of a platen, part of wafer chuck on which a wafer substrate may be placed. In at least one embodiment, wafer chuck surface may be substantially circular. Other suitable geometries of a wafer chuck surface may be within scope of disclosure. Here, “wafer” or “wafer substrate” may generally refer to a semiconductor wafer. In at least one embodiment, q semiconductor wafer, such as a silicon wafer, generally has a disc shape. In at least one embodiment, diameter of a wafer may range between 3 cm and 50 cm.

In at least one embodiment, plurality of mesas may be distributed in a substantially uniform pattern over surface of a wafer chuck assembly. In at least one embodiment, number per unit area of mesas may be substantially constant over substantially entire wafer chuck surface. In at least one embodiment, plurality of mesas has a non-uniform distribution pattern over wafer chuck surface. In at least one embodiment, number of mesas per unit area may have a radially varying distribution over substantially entire wafer chuck surface. In at least one embodiment, plurality of mesas may have uniform contact surface area and/or shape. In at least one embodiment, mesas may have varying contact surface geometries (e.g., contact area size variations) over portions of wafer chuck surface. In at least one embodiment, for all mesa distribution patterns, combined area fraction of plurality of mesas may be at least 3% of wafer chuck surface area, hence, wafer surface area.

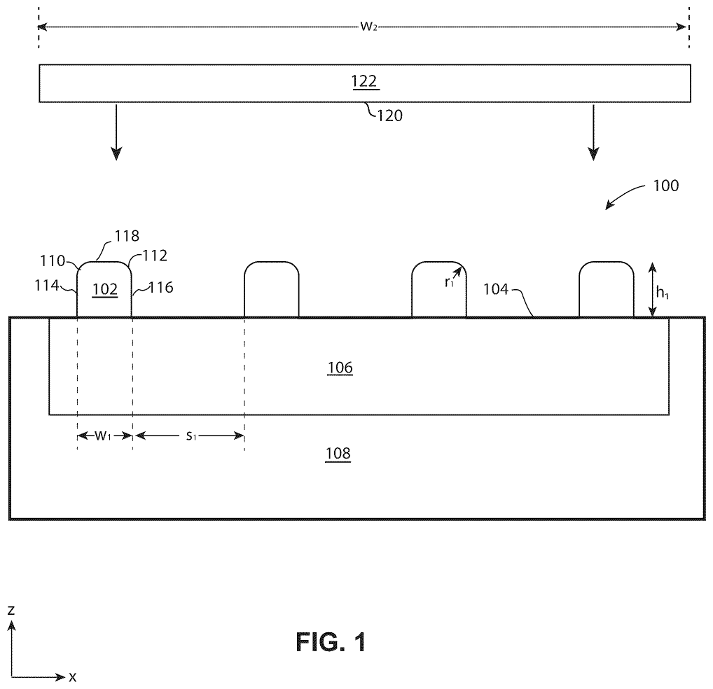

FIG. 1 illustrates a cross-sectional view of wafer chuck assembly 100, in accordance with at least one embodiment. In at least one embodiment, wafer chuck assembly 100 comprises a plurality of mesas 102 distributed on wafer chuck surface 104 of wafer chuck 106. In at least one embodiment, wafer chuck surface 104 may be substantially circular. Wafer chuck 106 may be seated on pedestal 108. In at least one embodiment, wafer chuck assembly 100 may generally comprise wafer chuck 106 and pedestal 108. In at least one embodiment, mesas 102 may have a width w1. In at least one embodiment, width w may range between 100 mils to 250 mils (e.g., approx. 2.50 mm to 6 mm). In at least one embodiment, mesas 102 may have a separation distance s₁ between adjacent mesas 102. In some embodiments, s₁ may range between 100 mils to 1000 mils. In at least one embodiment, mesas 102 may have a z-height h₁ that may range between 10 mils (e.g., approx. 250 microns) to 100 mils (e.g., approx. 2.5 mm).

In at least one embodiment, mesas 102 may comprise top edges 110 and 112 between sidewalls 114 and 116 and contact surface 118. Here, “contact surface” may generally refer to an uppermost portion or top surface of mesas 102 (and of other mesa embodiments disclosed herein), which touches (e.g., contacts) an overlying substrate, such as semiconductor wafer. In at least one embodiment, contact surface may be interface with overlying substrate and mesa. In at least one embodiment, semiconductor wafer may have a disc shape, comprising substantially flat surfaces. In at least one embodiment, contact surface may be planar or slightly curved, but generally not pointed. Herein, contact surfaces of disclosed mesa embodiments are planar. Herein, contact surfaces may be substantially smooth or have a texture. In at least one embodiment, contact surfaces 118 of mesas 102 may have an area of contact with an overlying substrate, such as a semiconductor wafer. In at least one embodiment, for a plurality of mesas, total contact area with an overlying wafer substrate may be calculated for example as contact area of an individual mesa multiplied by total number of mesas on a wafer chuck surface. In at least one embodiment, contact surface area of a plurality of mesas may be give as a percentage of surface area of a wafer chuck surface.

In at least one embodiment, contact surfaces of disclosed mesas may be bordered by top edges. Here, “top edge” may generally refer to intersection of contact surface with mesa sidewall. In at least one embodiment, top edges are upper edges of mesa. In at least one embodiment, top edges may be round or sloped to eliminate sharp edges that may contribute to damage of a wafer backside.

In at least one embodiment, top edges 110 and 112 may present an oblique or orthogonal angle to a radial direction of wafer chuck surface 104. In at least one embodiment of wafer chuck assembly 100, backside 120 of wafer substrate 122 may be contacted to mesas 102. In at least one embodiment, wafer chuck 106 may be heated to elevated temperatures for thermal cycling of wafer substrate 122 during processing. In at least one embodiment, during thermal cycling, wafer substrate 122 may expand and contract. In some embodiments, top edges 110 and 112 may be leading edges of mesas 102 relative to wafer backside 120. Here, “leading edge” may generally refer to one or more top edges near contact surface of a mesa. In at least one embodiment, leading edge may be normal to or parallel to direction of thermal expansion or contraction of a wafer that may occur during thermal cycling. Because of radial symmetry of wafer, thermal expansion and contraction may generally occur along radial directions. In at least one embodiment, leading edge may be shaped by rounding, sloping or by other geometric design to avoid sharp edges, mitigating marring and scratching during thermal expansion and contraction of wafer.

In at least one embodiment, top edges 110 and 112 may be rounded or sloped to mitigate scratching of layers or films on wafer backside 120. In at least one embodiment, top edges 110 and 112 may have at least one rounded edge having a suitable radius of curvature r₁ that permits sliding of mesas 102 over wafer backside 120. In at least one embodiment, top edges 110 and 112 may extend around contact surface 118 of mesas 102.

In at least one embodiment, contact surface 118 may be substantially planar. In at least one embodiment, a substantially planar contact surface 118 may be advantageous over a single point or small surface area contact such as a hemispherical contact surface, for example. In at least one embodiment, a planar contact surface 118 may have a lower contact pressure on wafer backside 120 than a hemispherical or pointed surface.

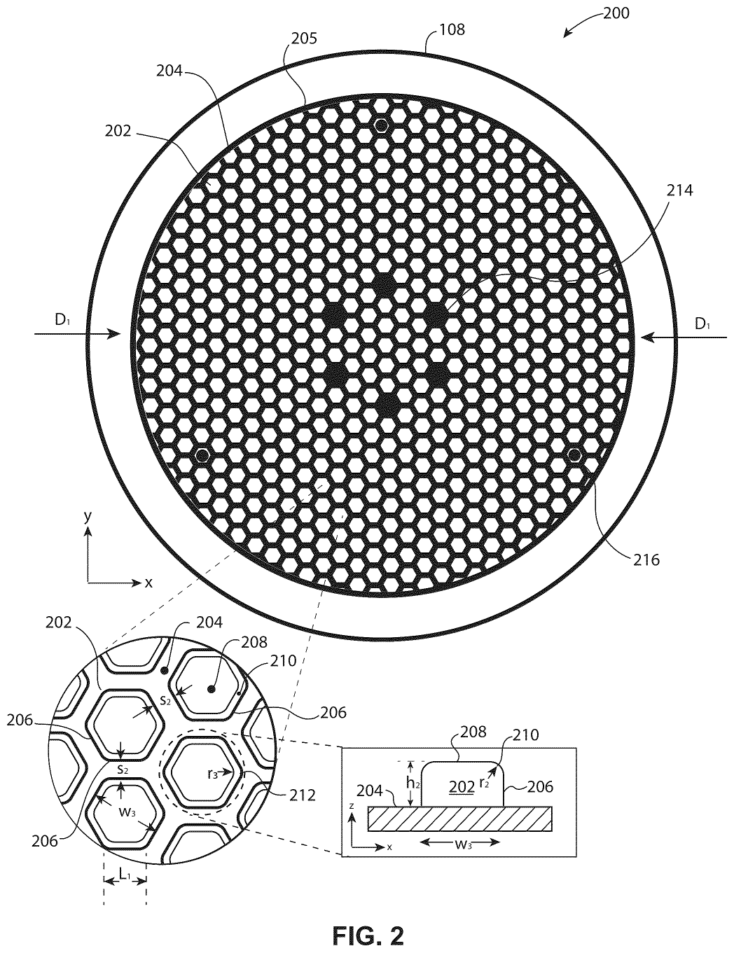

FIG. 2 illustrates a plan view of wafer chuck assembly 200 comprising a plurality of hexagonal mesas 202 distributed on surface 204 of wafer chuck 205, in accordance with at least one embodiment. In at least one embodiment, wafer chuck 205 may have a diameter D₁ ranging between 100 mm to 300 mm, for example. In at least one embodiment, wafer chuck 205 may be seated on pedestal 108 as shown. In at least one embodiment, mesas 202 may are arranged in a uniform pattern over wafer surface 204 as shown in figure. In at least one embodiment, mesas 202 are arranged in a hexagonal close-packed pattern, substantially filling circular wafer chuck surface 204.

Here, “close-packed” or “closed-packed distribution” may generally refer to geometrical arrangements to minimize spacing between substantially identical individual objects within an array of objects. In at least one embodiment, minimal spacing results in a maximal packing density of array of identical objects within boundaries of a defined surface or a volume. In at least one embodiment, “hexagonal close packed” may generally refer to a two-dimensional packing geometry where an object in a plurality of objects may be surrounded by six other identical objects in such a way that six neighboring objects are centered at vertices of a symmetrical hexagon, with surrounded object at center of hexagon. In at least one embodiment, in a hexagonally close-packed array, a defined area may be maximally filled with identical objects. In at least one embodiment, objects may have circular or polygonal horizontal cross sections. In at least one embodiment, for maximal packing within a defined surface area or volume, circular objects (e.g., cylindrical pillars) may touch at least at one point or have a closest spacing that may be 10% or less of diameter of circular objects. In at least one embodiment, sidewalls of polygonal objects may also touch or have a closest spacing that may be 10% or less of width of object.

Here, dark lines between mesas 202 (e.g., shown as white hexagons) are spaces between adjacent mesas 202. In at least one embodiment, mesas 202 may fill between 70% and 90% of wafer chuck surface 204. In at least one embodiment, degree of surface fill may depend on width w₂ of mesas 202 and spacing s₂ between sidewalls 206 of adjacent mesas 202, as shown in inset. In at least one embodiment, mesas 202 have a symmetrical hexagonal cross-section (e.g., mesas 202 having substantially equal polygonal cross sections and peripheral dimensions). In at least one embodiment, mesas 202 may have any suitable polygonal cross-section.

In at least one embodiment, other suitable polygonal symmetrical or non-symmetrical cross-sectional shapes (e.g., square, rectangular, parallelepiped or trapezoidal, alone or in combination with other suitable polygonal shapes such as triangles, pentagons and hexagons) may be employed. In at least one embodiment, hexagonal mesas 202 are equally spaced by distance s₂ from neighboring adjacent mesas 202 on all six sides. In at least one embodiment, mesas 202 are substantially symmetrical. For example, all six sidewalls 206 have length L₁. In at least one embodiment, mesas 202 may be asymmetric. For example, one or more of sidewalls 206 may have a length that may be different from adjacent sidewalls on same mesa 202 (not shown). In at least one embodiment, sidewalls 206 may be substantially non-vertical, having a slope.

In at least one embodiment, mesas 202 comprise contact surfaces 208. In some embodiments, contact surfaces 208 may be substantially planar as noted above for contact surface 118. In at least one embodiment, top edges 210 are rounded. In at least one embodiment, top edges 210 may have a radius of curvature r₂. In at least one embodiment, r₂ may be adjusted to optimize contact area of contact surfaces 208. In at least one embodiment, vertices 212 are also rounded, for example, having a radius of curvature r₃. In at least one embodiment, top edges 210 and vertices 212 may be rounded to mitigate damage to layers and/or films that may be on a wafer backside (e.g., backside 120).

In at least one embodiment, number of mesas 202 per unit area of wafer chuck surface 204 may be constant. In at least one embodiment, coverage of wafer chuck surface 204 by hexagonally close-packed mesas 202 may be approximately 70%. In at least one embodiment, area fraction of wafer chuck surface 204 that may be occupied by contact surfaces 208 may be controlled by adjusting space distance s₂ and radius of curvature r₂ of rounded top edges 210. In at least one embodiment, increasing r₂ may reduce contact area of mesas 202. In at least one embodiment, while a close-packed pattern as that shown in FIG. 2 may provide near maximal contact area, other less dense distribution patterns for mesas 202 may be employed to tailor contact area to a suitable value.

In at least one embodiment, clamping loads may be generated by electrostatic clamping or vacuum clamping of a wafer substrate (e.g., wafer substrate 122) to wafer chuck 205. In at least one embodiment, a particular area fraction of a wafer substrate (e.g., occupied by contact surfaces 208 of mesas 202) may be optimized for reducing clamping load per mesa to a desired level. In at least one embodiment, greater a surface fraction occupied by contact surfaces 208, lower a clamping load may be carried by individual mesas 202. In at least one embodiment, an exemplary advantage of reducing clamping load per mesa 202 may be reduction of indentation or penetration of a soft photoresist layer on wafer backside may be reduced or eliminated by providing a high contact area. In at least one embodiment, while damage to backside films and layers may be reduced by increasing contact area, contact area may be optimized to mitigate generation of particles. In at least one embodiment, particles that may be created by friction between contact surfaces and wafer backside may be isolated between adjacent mesas 202. In at least one embodiment, mesas may have a height h₂ that may be optimized to separate contact surfaces 208 from wafer chuck surface 204. In at least one embodiment, h₂ may range between 0.01 mm (10 microns) and 0.25 mm (250 microns). In at least one embodiment, particles may fall below contact surfaces 208, mitigating particulate contamination of backside surfaces.

In at least one embodiment, wafer chuck assembly 200 may be a vacuum wafer chuck assembly, comprising vacuum ports 214 on wafer chuck surface 204. Here, “vacuum port” may generally refer to a connection point in a vacuum line. In at least one embodiment, wafer chuck assembly 200 may include lift pin ports 216, from which lift pins (not shown) may rise to lift a wafer substrate (e.g., wafer substrate 122, FIG. 1) from contact surfaces 208. In at least one embodiment, vacuum ports 214 may be arranged in a symmetrical pattern, such as hexagonal pattern shown in figure. In at least one embodiment, during operation of wafer chuck assembly 200, a wafer substrate (e.g., wafer substrate 122) may be placed on wafer chuck 205. In at least one embodiment, wafer substrate may be contacted to plurality of mesas 202. In at least one embodiment, backside of substrate (e.g., wafer backside 120) may be offset from wafer chuck surface 204 by height h₂ of mesas 202. Vacuum clamping may be created by suction of ambient gas through vacuum ports 214, creating a low pressure within spaces in between mesas 202. In at least one embodiment, height h₂ of mesas 202, may be adjusted for optimal vertical offset of a wafer substrate for optimal vacuum clamping requiring adjustment of an open volume below substrate for a particular pressure differential between top and bottom sides of wafer substrate.

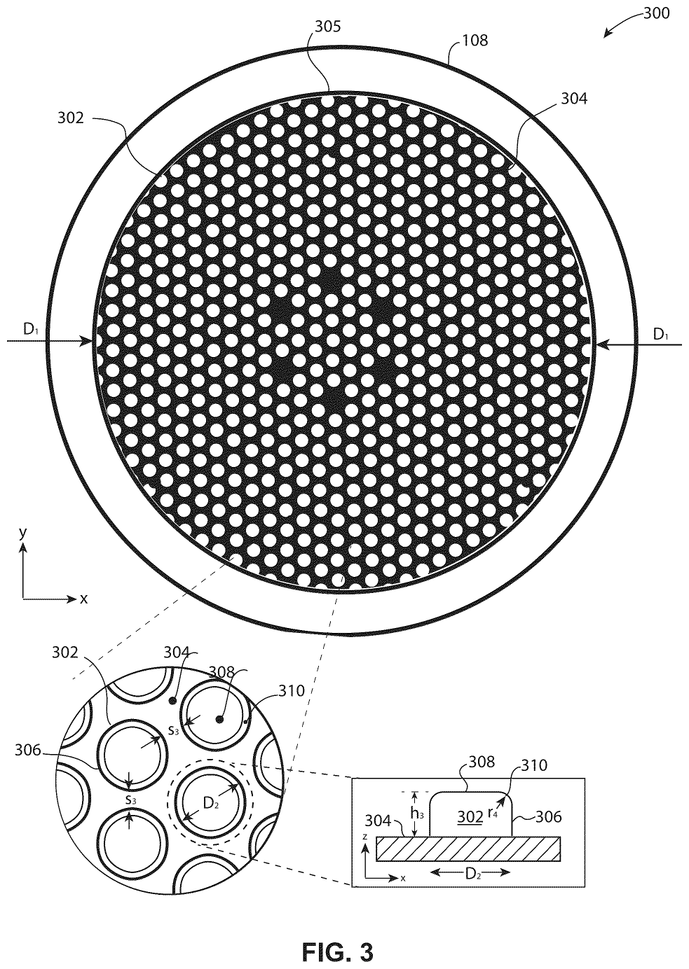

FIG. 3 illustrates a plan view of wafer chuck assembly 300, comprising a plurality of mesas 302 distributed over surface 304 of wafer chuck 305, in accordance with at least one embodiment. In at least one embodiment, wafer chuck 305 may have a diameter D₁ ranging between 100 mm to 300 mm, for example. In at least one embodiment, wafer chuck 305 may be seated on pedestal 108, as shown. In at least one embodiment, mesas 302 may be distributed uniformly over wafer chuck surface 304 in a hexagonal close-packed pattern to maximize contact surface area to a wafer substrate (e.g., wafer substrate 122). In at least one embodiment, area fraction of a wafer contacted by mesas 302 in a close-packed pattern may be between 3% and 90%. In illustrated embodiment, mesas 302 are substantially identical (e.g., mesas 302 having substantially equal circular cross sections) cylindrical mesas or pillars having a circular horizontal cross-section having a diameter D₂. In at least one embodiment, D₂ may range between 100 and 300 mils (e.g., approx. 2.5 mm to 7.5 mm). In at least one embodiment, other suitable round shapes (e.g., oval and/or elliptical) may be employed. In at least one embodiment, circular or round mesas may be combined with other suitable round and/or polygonal shapes.

In at least one embodiment, mesas 302 may have a spacing s₄ between neighboring mesas 302, as shown in inset. Spacing s₄ may be adjusted to optimize contact surface area. In at least one embodiment, spacing s₄ may range between 80 to 160 mils (e.g., approx. 2 mm to 4 mm). In at least one embodiment, mesas 302 may have a z-height h₃ between 0.01 mm and .25 mm.

In at least one embodiment, mesas 302 may comprise rounded top edges 310 between contact surface 308 and sidewall 306. In at least one embodiment, rounded top edges 310 may have a radius of curvature r₄, as shown in inset. As noted above, radius of curvature r₄ may be tailored for minimal impact on backside films or layers during thermal cycling of wafer substrate during processing. In at least one embodiment, simultaneously, radius of curvature r₄ may be adjusted for optimal area of contact surfaces 308.

In at least one embodiment, total contact area may be sum of contact surfaces 308 of all mesas 302. In at least one embodiment, wafer chuck surface 304 having a diameter D₁ of approximately 300 mm (e.g., 11.2 in diameter, area 98.5 in²) may comprise, for example, 2259 substantially identical mesas 302 having a center-to-center spacing s₄ of approximately 230 mils (e.g., approx. 5.7 mm). In at least one embodiment, contact surface 308 (e.g., having a diameter D₂ of 120 mils) of individual mesa 302 may have an area of 0.011 in² (e.g., approx. 7.1 mm²). In at least one embodiment, total area contacting a wafer substrate may be approximately 25.5 in² (e.g., approx. 164.5 cm²). In at least one embodiment, contact area fraction by mesas 302 may be approximately 26%, exceeding a threshold of 3%.

In at least one embodiment, a pressure differential of 10 torr (e.g., 0,193 psi) between top side and backside of a wafer substrate clamped to wafer chuck assembly 300 may be developed over a wafer vacuum-clamped on wafer chuck assembly 300. In at least one embodiment, total atmospheric (e.g., clamping) load on wafer may be approximately 19 pounds (e.g., approx. 8.6 kg). In at least one embodiment, load may be distributed substantially equally over plurality of mesas 302. In at least one embodiment, load per mesa 302 may be approximately 0.0084 pounds (e.g., approx. 3.8 grams, 0.76 psi). In at least one embodiment, a threshold pressure per mesa may be lower than 0.76 psi, for example.

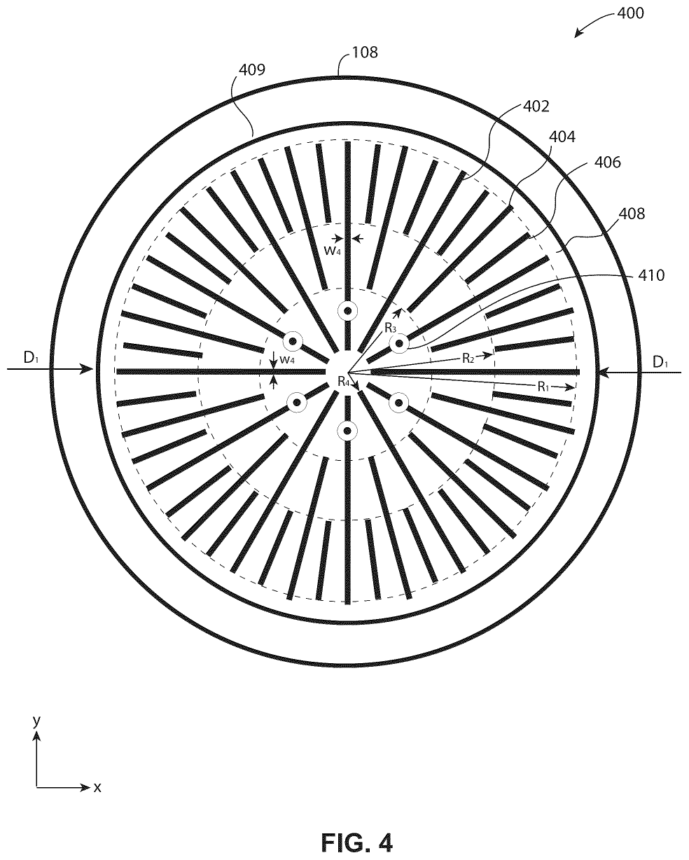

FIG. 4 illustrates a plan view of wafer chuck assembly 400, in accordance with at least one embodiment. In at least one embodiment, wafer chuck assembly 400 comprises a plurality of line mesas comprising a first subset comprising line mesas 402, a second subset comprising line mesas 404 and a third subset comprising line mesas 406. In at least one embodiment, collections of line mesas 402, 404, and 406 comprise subsets of plurality of mesas. In at least one embodiment, line mesas 402, 404, and 406 may be distributed in a polar geometry. Here, “polar geometry” may generally refer to an angular distribution (e.g., in polar coordinates), where line mesas may be repeated at regular or irregular angles around a circular surface. In at least one embodiment, line mesas 402-406 are shaped substantially as lines having three different lengths. In at least one embodiment, mesas 402 have longest length, and mesas 406 have shortest length. In at least one embodiment, mesas 402, 404, and 406 are distributed symmetrically over surface 408 of wafer chuck 409. In at least one embodiment, while mesas 402, 404, and 406 are repeated in order at multiple angular intervals, they may be distributed in any suitable manner. In at least one embodiment, wafer chuck 409 may be seated on pedestal 108, as shown. In at least one embodiment, wafer chuck 409 may have a diameter D₁ ranging between 100 mm to 300 mm. In at least one embodiment, mesas 402, 404, and 406 are distributed in an angularly symmetrical (e.g., having substantially same angular separation in angular degrees) but radially non-uniform pattern, as shown. In at least one embodiment, density of mesas 402, 404 and 406 may increase toward periphery of wafer chuck surface 408 to support radially increasing clamping load, for example.

In at least one embodiment, mesas 402, 404, and 406 may be line-shaped structures, extending between radii R₁, R₂, and R₃, respectively. In at least one embodiment, mesas 402 are longest of three mesa subsets, extending between radii R₁ and R₄. In at least one embodiment, some mesas 402 are interrupted by vacuum ports 410. In at least one embodiment, mesas 404 have medium length, extending between radii R₁ and R₃. In at least one embodiment, mesas 406 are shortest of tree mesas, extending between radii R₁ and R₂ near periphery of wafer chuck surface 408.

In at least one embodiment, mesas 402, 404, and 406 may have substantially same width w₄. In at least one embodiment, mesas may have different widths. In at least one embodiment, mesas 402, 404, and 406 may be interspersed as shown in figure. In at least one embodiment, mesas 402 are repeated every 30 degrees around wafer chuck surface 408. In at least one embodiment, mesas 404 are repeated every 30 degrees and are distributed between mesas 402. In at least one embodiment, mesas 406 repeat every 15 degrees between adjacent mesas 402 and 404. In at least one embodiment, depending on width w₄ and number of mesas desired, mesas (e.g., mesas 402, 404, and 406) may be placed at any suitable angular position.

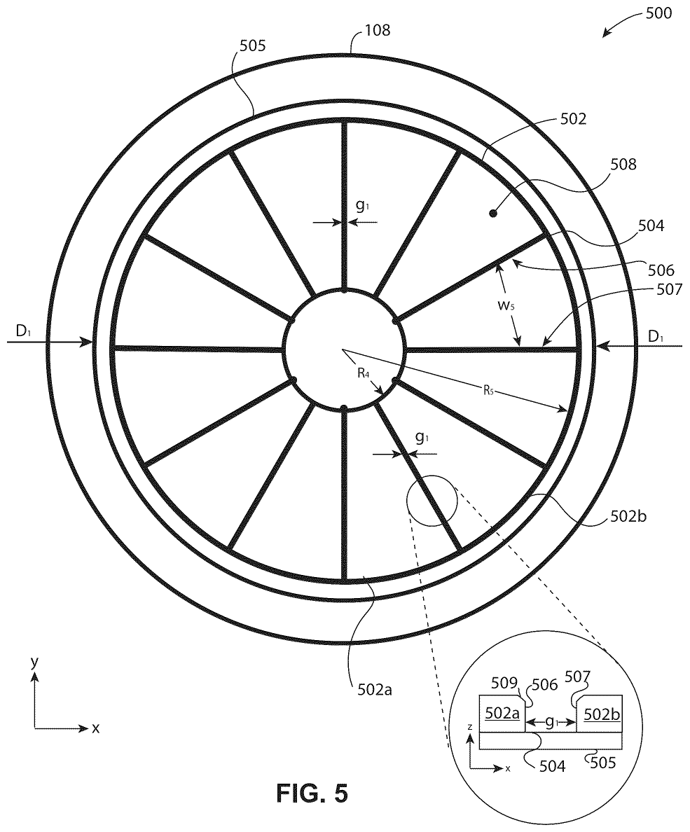

FIG. 5 illustrates a plan view of wafer chuck assembly 500, comprising a plurality of wedge-shaped mesas 502 arranged in a symmetrical angular distribution around surface 504 of wafer chuck 505, in accordance with at least one embodiment. Plan view of FIG. 5 shows wafer chuck 505 seated on pedestal 108, according to at least one embodiment. In at least one embodiment, wafer chuck 505 may have a diameter D₁ ranging between 100 mm to 300 mm. In at least one embodiment, mesas 502 are substantially wedge shaped, comprising diverging sidewalls 506 fanning out towards periphery from a central region of surface 504. In at least one embodiment, mesas 502 may have a width w₅ that increases with increases with radial distance from center of surface 504. Here, “wedge shaped” may generally refer to a substantially triangular shape of an object. In at least one embodiment, a general definition of a wedge may be a triangular or trapezoidal shape that has non-parallel sidewalls subtending an angle between nonparallel sidewalls and a width that increases with distance from one end to another.

In at least one embodiment, mesas 502 are substantially identical. In some embodiments, sidewalls 506 and 507 of mesas 502 extend between radii R₄ and R₅, spanning a radial distance R₅-R₄. In at least one embodiment, mesas 502 may be arranged in a symmetrical close-packed pattern as shown. In at least one embodiment, as shown in inset, sidewalls 506 and 507 belonging to adjacent mesas 502a and 502b are also adjacent, separated by a distance g₁. In at least one embodiment, mesas 502 may comprise contact surfaces 508 that may provide large contact area. In at least one embodiment, contact surfaces 508 may join sidewalls 506 and 507 by blunted top edges 509, which are shown as sloping transitions between sidewalls 506 and 507 and contact surfaces 508. In at least one embodiment, top edges 509 may be rounded edges, such as leading edges 210, shown in FIG. 2.

In at least one embodiment, sidewalls 506 and 507 extend along radial vectors of wafer chuck surface 504. In at least one embodiment, extension of sidewalls 506 and 507 along radial vectors may substantially eliminate or completely avoid scratching of a wafer backside surface during thermal cycling of an attached wafer. as edges for mesas 502. In at least one embodiment, slope or roundness of top edges 509 may also mitigate marring of wafer backsides during thermal cycling. In at least one embodiment, during thermal cycling of a wafer substrate clamped to wafer chuck assembly 500, radially extending top edges 509 of mesas 502 may be substantially parallel to direction of thermal expansion and contraction. In at least one embodiment, by consequence, top edges 509 may not be prone to scratch a wafer backside during thermal expansion and contraction. In at least one embodiment, as mesas 502 may also undergo thermally-induced expansion and contraction during thermal cycling, coefficient of thermal expansion (CTE) of mesas 502 may be engineered to substantially match CTE of wafer so that relative motion between mesas 502 and a wafer may be minimized.

In at least one embodiment, wedge shape of mesas 502 may enable uniform radial as well as angular distribution of contact surface over wafer chuck surface 504. In at least one embodiment, as clamping force over a wafer substrate (e.g., wafer substrate 122) may increase parabolically (e.g., as radius or diameter squared), fanning structure of mesas 502 may distribute clamping forces evenly over wafer surface as contact area also increases parabolically in radial direction.

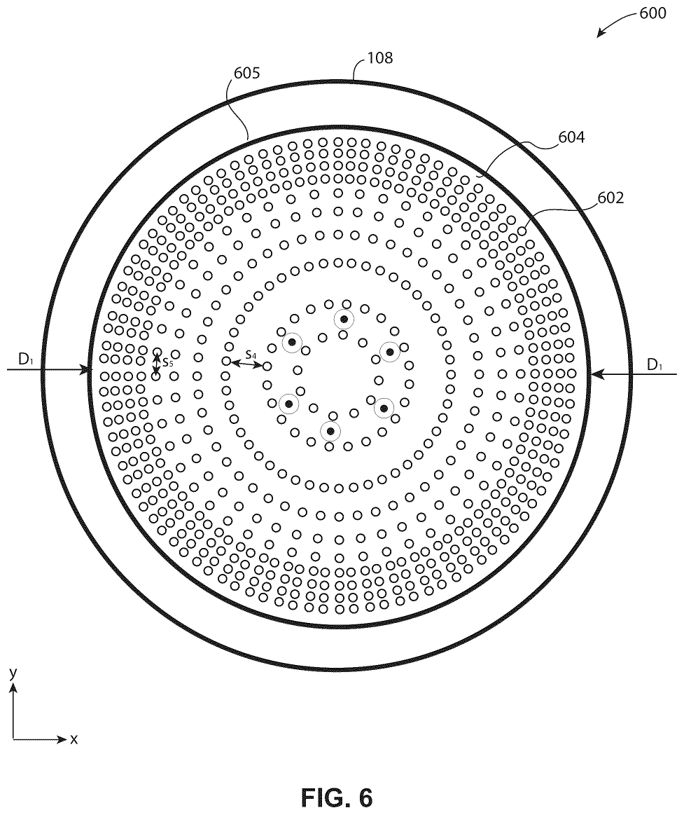

FIG. 6 illustrates a plan view of wafer chuck assembly 600 comprising a plurality of mesas 602 distributed on surface 604 of wafer chuck 605, seated on pedestal 108 as shown, in accordance with at least one embodiment. In at least one embodiment, wafer chuck 605 may have a diameter D₁ ranging between 100 mm to 300 mm. In at least one embodiment, mesas 602 are substantially identical. In at least one embodiment, mesas 602 may have circular horizontal cross-sections like mesas 302, described herein. In at least one embodiment, mesas 602 have a logarithmic radial distribution. In at least one embodiment, mesas 602 may be distributed along multiple concentric circles having a logarithmic radial spacing s₄. In at least one embodiment, concentric circles may be grouped into several annuli. Here, “annulus” may generally refer to multiple circular portions of surface 604 extending between radii. Plural form of annulus is “annuli.” In at least one embodiment, logarithmic radial separation distance s₄ may decrease substantially toward periphery of wafer chuck surface 604. In at least one embodiment, distribution of mesas 602 may be concentrated toward periphery of wafer chuck surface 604. In at least one embodiment, periphery of a wafer clamped to wafer chuck assembly 600 may have greatest contact area from concentrated distribution of outermost mesas 602. In at least one embodiment, inner regions near center of wafer, having smallest clamping forces, also have proportionally smaller contact area from a more rarified distribution of mesas 602. In at least one embodiment, radial distribution of contact surface may follow parabolically increasing distribution of clamping force over a wafer clamped to wafer chuck 605.

In at least one embodiment, angular distribution of mesa 602 may be substantially symmetric, as shown. In at least one embodiment, mesas 602 may repeat at angular increments of 15 degrees around wafer chuck surface 604, forming concentric circular distributions of mesas 602 along a logarithmic progress of radial distances. In at least one embodiment, at individual radii, mesas may have a uniform spacing s₅ in angular direction. In at least one embodiment, spacing s₅ may increase as radial distances increase toward periphery. In at least one embodiment, mesas 602 near periphery may repeat at smaller angular increments. In at least one embodiment, peripheral mesas 602 may repeat at angular increments of 7.5 degrees, as shown.

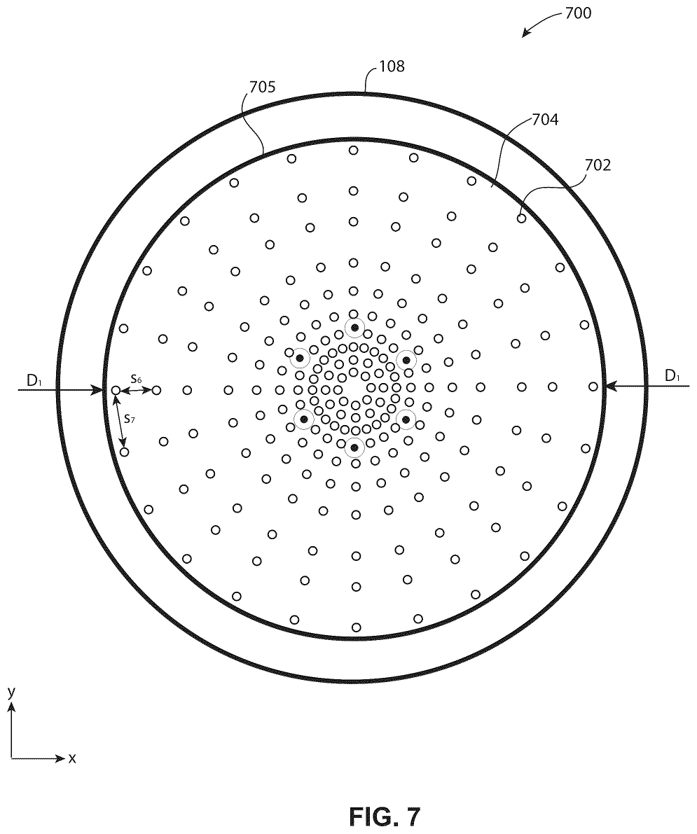

FIG. 7 illustrates a plan view of wafer chuck assembly 700 comprising a plurality of mesas 702 distributed over surface 704 of wafer chuck 705, in accordance with at least one embodiment. In at least one embodiment, wafer chuck 705 may be seated on pedestal 108, as shown. In at least one embodiment, wafer chuck 705 may have a diameter D₁ ranging between 100 mm to 300 mm. In at least one embodiment, mesas 702 are substantially identical, having a circular horizontal cross section of uniform diameter. as illustrated in FIG. 2. In at least one embodiment, mesas 702 may have a polygonal horizontal cross section.

In at least one embodiment, mesas 702 are radially distributed in an increasing logarithmic progression. In at least one embodiment, radial separation distance s₆ may increase substantially logarithmically toward periphery of wafer chuck surface 704. In at least one embodiment, number of mesas 702 per unit area may be concentrated toward center of wafer chuck surface 704, diminishing toward periphery. In at least one embodiment, clamping forces may be stronger near center of clamped wafer. In at least one embodiment, if height clearance (e.g., z-height h₂ or h₃) of mesas 702 is small (e.g., less than 10 mils), a radial pressure differential may exist while vacuum pumping is active. In at least one embodiment, pressure near center of wafer chuck surface 704 may be lower than at periphery, increasing clamping forces closer to center of a wafer substrate than at periphery.

In at least one embodiment, mesas 702 may have a uniform angular distribution. For example, mesas 702 may repeat at angular increments of 15 degrees uniformly around wafer chuck surface 704, as shown. In at least one embodiment, spacing s₇ between angularly adjacent mesas 702 may be increase logarithmically toward periphery.

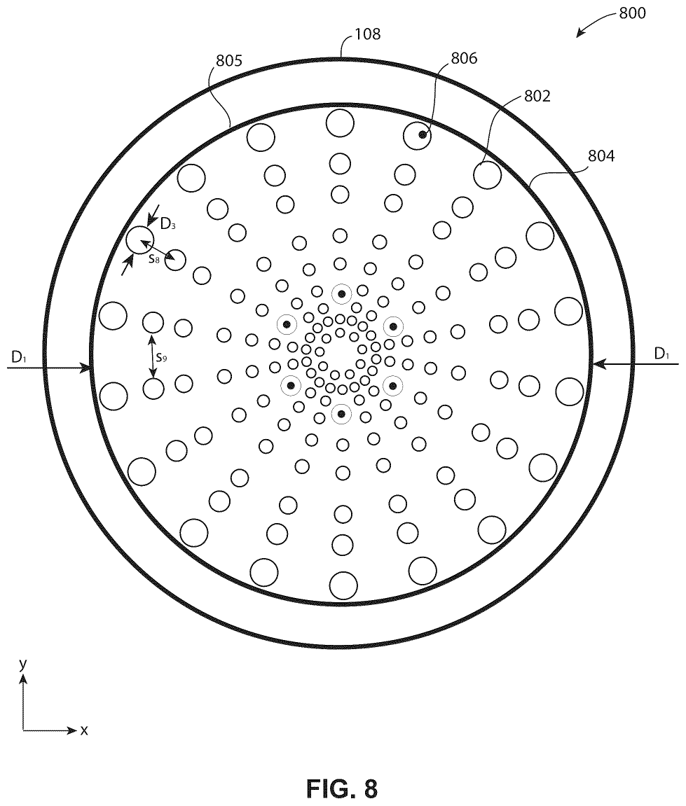

FIG. 8 illustrates a plan view of wafer chuck assembly 800 comprising a plurality of mesas 802 distributed over surface 804 of wafer chuck 805, according to at least one embodiment. In at least one embodiment, wafer chuck 805 may be seated on pedestal 108, as shown. In at least one embodiment, wafer chuck 805 may have a diameter D₁ ranging between 100 mm to 300 mm. In at least one embodiment, mesas 802 are substantially cylindrical, having a circular horizontal cross section of diameter D₃. In at least one embodiment, D₃ increases in a logarithmic progression toward periphery. Here, “logarithmic progression” may generally refer to an increase in diameter of mesas that follow a logarithmic relationship with radial position of mesa. In at least one embodiment, a doubling of distance from center of chuck surface of position of a mesa corresponds to a 30% increase in diameter of mesa. In at least one embodiment, mesas 802 are concentrically arranged in a uniform angular distribution having an angular increment of 15 degrees between concentric mesas 802.

In at least one embodiment, mesas 802 may be arranged along logarithmically spaced concentric circles having a logarithmic progression of center-to-center spacing s₈. In at least one embodiment, s₈ increases logarithmically toward periphery. In at least one embodiment, diameters D₃ of concentric mesas 802 increase in a logarithmic progression toward periphery of wafer chuck surface 804, as shown. In at least one embodiment, all mesas 802 having same diameter D₃ may be arranged on one concentric circle. At progressively increasing radial distances, mesas having same diameter D₃ may be arranged along concentric circles. In at least one embodiment, while a logarithmic progression in both diameter D₃ and radial spacing s₈ is implemented, other suitable non-linear and/or linear relationships may be equally employed.

In at least one embodiment, mesas 802 may have a uniform angular distribution around wafer chuck surface 804. In at least one embodiment, mesas may repeat at angular increments of 15 degrees, resulting in a linear spacing s₉ between adjacent mesas 802.

In at least one embodiment, clamping loads on mesas 802 from a wafer substrate may increase parabolically (e.g., as wafer radius squared) toward periphery. In at least one embodiment, as diameter D₃ of mesas 802 may be related to area of contact surfaces 806, a logarithmic increase of contact area (e.g., an increasing logarithmic progression of diameters D₃) may approximately track parabolic increase in load. In at least one embodiment, clamping loads may be evenly distributed among mesas 802. In at least one embodiment, diameters D₃ may be optimized to tailor a particular clamping load profile.

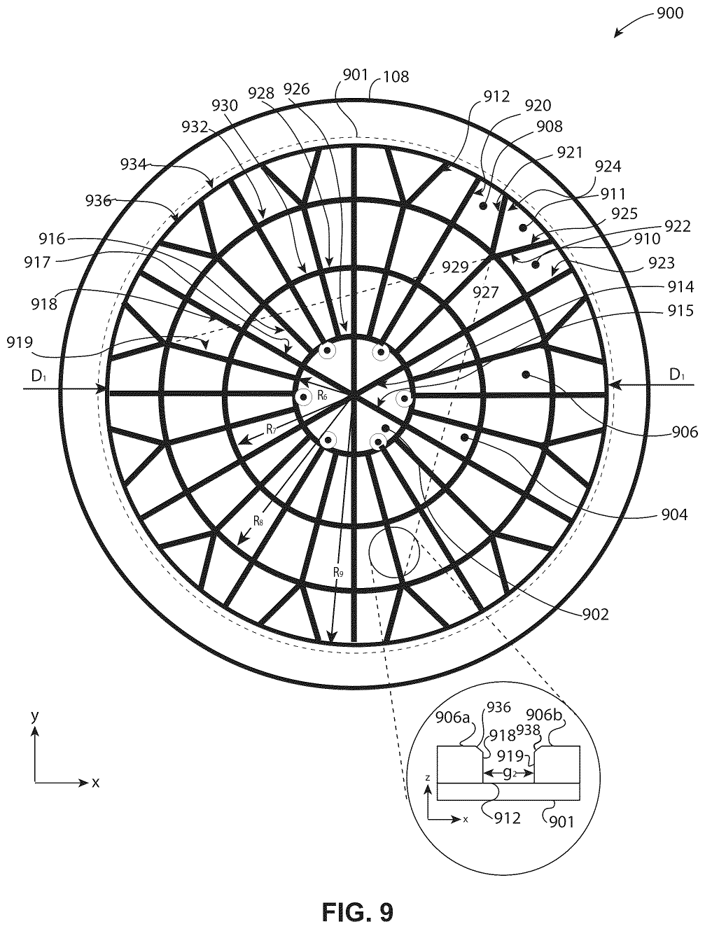

FIG. 9 illustrates a plan view of wafer chuck assembly 900, in accordance with at least one embodiment. In at least one embodiment, wafer chuck assembly 900 comprises a plurality of mesas 902, 904, 906, 908, 910, and 911 distributed on surface 912 of wafer chuck 901, which may be delineated by dashed circle. In at least one embodiment, wafer chuck 901 may be seated on pedestal 108, as shown. In at least one embodiment, wafer chuck 901 may have a diameter D₁ ranging between 100 mm to 300 mm.

In at least one embodiment, mesas 902-911 may be tiled over wafer chuck surface 912. Contact surfaces of mesas 902-911 are shown, in accordance with at least one embodiment. In at least one embodiment, individual mesas are separated from neighboring mesas by a relatively narrow gap, defined below. In at least one embodiment, plurality of mesas may be divided into a first plurality of mesas, a second plurality of mesas, a third plurality of mesas, and a fourth plurality of mesas. In at least one embodiment, first plurality of mesas comprises a first subset comprising collections of mesas 902. In at least one embodiment, second plurality of mesas comprises a second subset comprising a collection of mesas 904. In at least one embodiment, third plurality of mesas comprises a third subset comprising a collection of mesas 906. In at least one embodiment, fourth plurality of mesas comprises a fourth plurality comprising a collection of mesas 908, 910, and 911. In at least one embodiment, first, second, third and fourth subsets comprising mesas 902 904, 906, 908, 910, and 911 may be respectively distributed within concentric annuli on wafer chuck surface 912.

In at least one embodiment, individual mesas 902 may comprise sidewalls 914 and 915 that extend along a first radial direction and a second radial direction, respectively. In at least one embodiment, radial directions, defined by polar coordinates r and q, wherein r is a radius and q is an angle, may repeat at substantially equal angular intervals q₀ for example, where q₀ may range between 15 and 60 degrees. In at least one embodiment, radial directions may generally be located at any angular position on wafer chuck surface 912. Here, “radial direction” may generally refer to a line or direction that extends along an imaginary radial line passing through center of wafer chuck surface 912. In at least one embodiment, radial direction may be a radial vector having coordinates r and q, for example, extending from center of wafer chuck surface to circumference.

In at least one embodiment, sidewalls 914 and 915 extend a first radial distance between center of wafer chuck surface and a first radius R₆. In at least one embodiment, first and second radial directions may have a first angular separation on wafer chuck surface, for example, occurring every 60 degrees around wafer chuck surface 912, comprising six mesas 902.

In at least one embodiment, individual mesas 904 may comprise sidewalls 916 and 917 that extend along a third radial direction and a fourth radial direction, respectively. In at least one embodiment, third and fourth radial directions may have a second angular separation, for example, repeated every 20 degrees around wafer chuck surface 912. In at least one embodiment, sidewalls 916 or 917 of every third mesa 904 may be aligned with sidewalls 914 and 915 of individual mesas 902. In at least one embodiment, sidewalls 916 and 917 may extend over a second radial distance between radii R₆ and R₇, where second radial distance is R₇-R₆.

In at least one embodiment, individual mesas 906 may comprise sidewalls 918 and 919 that extend along a fifth radial direction and a sixth radial direction, respectively. In at least one embodiment, fifth and sixth radial directions may have a third angular separation, for example, repeated every 20 degrees around wafer chuck surface 912. In at least one embodiment, sidewalls 918 and 919 may align with sidewalls 916 and 917 of mesas 904. In at least one embodiment, sidewalls 918 and 919 may extend over a third radial distance extending between radii R₇ and R₈, where third radial distance is R₈-R₇.

In at least one embodiment, individual mesas 908 may comprise sidewall 920 that extends along a seventh radial direction and sidewall 921 that extends along a first non-diametric chord 927, indicated by dashed line labelled 927. In at least one embodiment, non-diametric chord 927 may extend at a first oblique angle relative to seventh radial direction. Here, “non-diametric chord” may generally refer to a chord of circular wafer chuck surface 912 that extends at oblique angles relative to any radial direction that passes through center of wafer chuck surface 912. In at least one embodiment, a non-diametric chord does not pass through center of wafer chuck surface 912. In at least one embodiment, sidewalls 920 and 921 may extend a fourth radial distance extending between radii R₈ and R₉, where fourth radial distance is R₉-R₈. R₉ may extend substantially from center of wafer chuck surface 912 to circumference of wafer chuck surface 912.

In at least one embodiment, individual mesas 910 may comprise sidewall 922 that extends along an eighth radial direction, and sidewall 923 that extends along a second non-diametric chord 929, indicated by dashed line labeled 929. In at least one embodiment, non-diametric chord 929 may extend at a second oblique angle relative to eighth radial direction. In at least one embodiment, second non-diametric chord 929 may be reflected across a mirror plane into first non-diametric chord 927, where first oblique angle may be equal to second oblique angle with respect to mirror plane cutting through diameter of wafer chuck surface 912. In at least one embodiment, like sidewalls 920 and 921, sidewalls 922 and 923 may also extend over fourth radial distance extending between radii R₈ and R₉, where fourth radial distance is R₉-R₈. In at least one embodiment, because of symmetry of first and second non-diametric chords 927 and 929, mesas 908 and 910 may be mirror images of one another.

In at least one embodiment, individual mesas 911 are triangular tiles sandwiched between mesas 908 and 910. In at least one embodiment, individual mesas 911 may comprise sidewall 924 extending along first non-diametric chord 927, and may be adjacent and parallel to sidewall 921 of mesa 908. In at least one embodiment, mesas 911 may also comprise sidewall 925 extending along second non-diametric chord 929, and may be adjacent and parallel to sidewall 922 of mesa 910. In at least one embodiment, sidewalls 924 and 925 may be seen to intersect at radius R₈, and diverge along non-diametric chords 927 and 929. In at least one embodiment, sidewalls 924 and 925 also extend between radii R₈ and R₉.

In at least one embodiment, mesas 902-911 may comprise leading edges 926, 928, 930, 932, 934 and 936, respectively, corresponding to mesas 902, 904, 906, 908, 910, and 911. In at least one embodiment, leading edges 926, 928, 930, 932, 934 and 936 may follow concentric circular arcs at increasing radial distances R₆, R₇, R₈, and R₉, as shown.

In at least one embodiment, inset in FIG. 9 shows a cross-sectional view taken through adjacent mesas 906a and 906b, showing sidewalls 918 and 919 separated by spacing distance g₂, in accordance with at least one embodiment. In at least one embodiment, mesas 906a and 906b comprise blunted top edges 936 and 938 that are sloped. In other embodiments, top edges 936 and 938 may be rounded. In at least one embodiment, all of mesas 902-911 may comprise blunted top edges similar or identical to top edges 936 and 938.

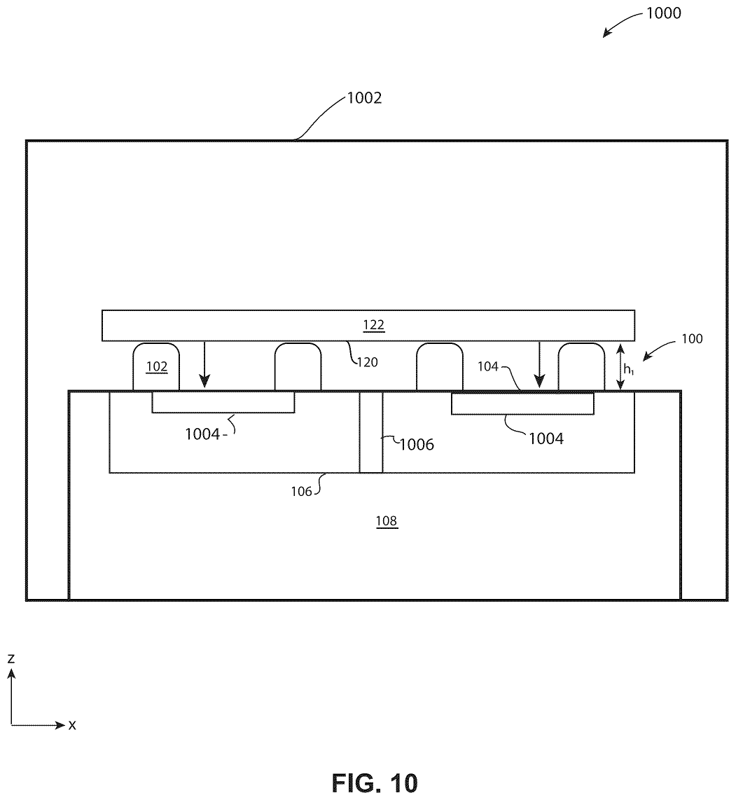

FIG. 10 illustrates a cross-sectional view of wafer processing apparatus 1000, in accordance with at least one embodiment. In at least one embodiment, wafer processing apparatus 1000 comprises wafer chuck assembly 100 within wafer processing chamber 1002. Here, “wafer processing chamber” may generally refer to a high vacuum chamber in which a wafer substrate may be introduced for processing operations. In at least one embodiment, wafer processing chamber may comprise components such as a wafer chuck for holding wafer substrate. In at least one embodiment, wafer processing chamber 1002 may comprise an antechamber (not shown) through which wafer substrate 122 may be introduced. In at least one embodiment, wafer processing chamber 1002 may comprise a lid that may be opened and closed to introduce and remove wafer substrate 122. Here, “wafer processing apparatus” generally refers to a semiconductor processing tool comprising a vacuum chamber, in which a wafer substrate may be placed for processing.

In at least one embodiment, wafer chuck 106 may be seated within pedestal 108. In at least one embodiment, wafer chuck surface 104 may comprise mesas 102, for example. In at least one embodiment, any of mesas 202, 302, 402, 502, 602, 702, and 802 disclosed above may be equally employed. In at least one embodiment, mesas 102 are distributed over wafer chuck surface 104. In at least one embodiment, wafer substrate 122 may be mounted on wafer chuck assembly 100 as shown. In at least one embodiment, wafer backside 120 may be contacted to mesas 102. In at least one embodiment, mesas comprise contact surfaces 118 that may contact at least 20% of area of wafer backside 120. In at least one embodiment, wafer chuck assembly 100 may comprise electrodes 1004 embedded within wafer chuck surface for electrostatic clamping (ESC) of wafer substrate 122 to mesas 102. Here, “electrodes” may generally refer to metallic structures that are electrically coupled to a voltage or power source. In at least one embodiment, “electrodes” may be contact electrodes for sparking and maintaining a plasma or may be clamping electrodes for electrostatic clamping of a wafer on a wafer chuck. In at least one embodiment, wafer chuck assembly 100 may alternatively comprise one or more vacuum ports 1006 for vacuum clamping of wafer substrate 122 to mesas 102. In at least one embodiment, mesas 102 may contact at least a threshold percentage (e.g., at least 3%) of wafer backside 120.

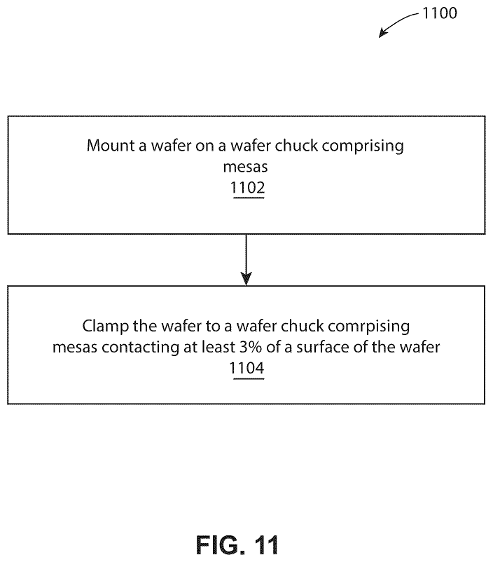

FIG. 11 illustrates flow chart 1100 summarizing an exemplary method for using wafer processing apparatus 1000, in accordance with at least one embodiment. In at least one embodiment, at operation 1102, a wafer substrate (e.g., wafer substrate 122) is mounted within a process chamber comprising a wafer chuck assembly (e.g., wafer chuck assembly 100 within wafer processing chamber 1002). In at least one embodiment, wafer may be mounted on a wafer chuck surface comprising a plurality of mesas (e.g., mesas 102 distributed on wafer chuck surface 104). In at least one embodiment, wafer has a structured layer or a film of a dielectric or photoresist on wafer backside, or side of wafer that may be contacted by plurality of mesas. In at least one embodiment, plurality of mesas may contact at least 3% (e.g., 3%-90%) of wafer substrate. In at least one embodiment, plurality of mesas may be distributed over wafer chuck surface to evenly distribute clamping forces. In at least one embodiment, by such a distribution, pressure over individual mesas due to a clamped wafer may be reduced below a threshold level.

In at least one embodiment, at operation 1104, wafer substrate may be clamped electrostatically by an ESC chuck as described above, or by vacuum applied to ports in wafer chuck surface. In at least one embodiment, clamping forces may be controlled by adjusting voltages of ESC electrodes or by adjusting a pressure differential between wafer chuck surface below wafer substrate and top surface of wafer substrate.

Following examples are provided that illustrate at least one embodiment. At least one embodiment, can be combined with at least another embodiment without changing scope of at least one embodiment.

Example 1: A wafer chuck assembly, comprising: a wafer chuck comprising a surface having a substantially circular geometry, the surface having a center and a first area; and a plurality of mesas distributed over the surface of the wafer chuck, wherein individual ones of the plurality of mesas extend a height above the surface of the wafer chuck, wherein the individual ones of the plurality of mesas comprise a contact surface, and wherein a second area substantially equals a sum of an area of the contact surface of the individual ones of the plurality of mesas is at least 3% of the first area.

Example 2: Wafer chuck assembly of Example 1, wherein the individual ones of the plurality of mesas comprise at least one leading edge that is rounded or sloped.

Example 3: Wafer chuck assembly of Example 1, wherein the second area is between 3% and 90% of the first area.

Example 4: Wafer chuck assembly of Example 1, wherein the height is between 0.01 mm and 0.25 mm.

Example 5: Wafer chuck assembly of Example 1, wherein the individual ones of the plurality of mesas comprise a substantially circular or polygonal cross section.

Example 6: Wafer chuck assembly of Example 5, wherein the individual ones of the plurality of mesas have a substantially equal diameter.

Example 7: Wafer chuck assembly of Example 5, wherein a diameter of the individual ones of the plurality of mesas increases with an increase in radial distance along the surface.

Example 8: Wafer chuck assembly of Example 8, wherein the individual ones of the plurality of mesas comprise a substantially polygonal plan view cross section, and wherein the individual ones of the plurality of mesas comprise substantially equal peripheral dimensions.

Example 9: Wafer chuck assembly of Example 9, wherein the substantially polygonal plan view cross section is substantially hexagonal.

Example 10: The wafer chuck assembly of Example 10, wherein the individual ones of the plurality of mesas are arranged in a close-packed distribution over the surface, and wherein adjacent individual ones of the plurality of mesas have a substantially equal pitch between adjacent individual ones of the plurality of mesas.

Example 11: Wafer chuck assembly of Example 10, wherein adjacent individual ones of the plurality of mesas have a pitch that increases with an increase in radial distance along the surface.

Example 12: Wafer chuck assembly of Example 12, wherein a radial distribution of a number of individual ones of the plurality of mesas per unit area decreases from the center to a periphery of the surface.

Example 13: Wafer chuck assembly of Example 10, wherein adjacent individual ones of the plurality of mesas have a pitch that decreases with an increase in radial distance along the surface

Example 14: Wafer chuck assembly of Example 14, wherein a radial distribution of a number of individual ones per unit area of surface increases from the center to a periphery of the surface.

Example 15: Wafer chuck assembly of Example 1, wherein the individual ones of the plurality of mesas comprise a wedge, wherein the wedge comprises a first sidewall that extends from a central region of the surface to a periphery of the surface and a second sidewall that extends from the central region to the periphery of the surface, and wherein the first sidewall of a first individual one of the plurality of mesas is adjacent to a second sidewall of a second individual one of the plurality of mesas.

Example 16: Wafer chuck assembly of Example 1, wherein first individual ones of the plurality of mesas are first line mesas that are distributed in a first polar geometry on the surface, wherein individual ones of the first line mesas extend a first radial distance along first radial directions on the surface, and wherein the first radial distance extends from substantially a center of the surface to substantially a periphery of the surface.

Example 17: Wafer chuck assembly of Example 1, wherein first individual ones of the plurality of mesas are first line mesas that are distributed in a first polar geometry on the surface, wherein individual ones of the first line mesas extend a first radial distance along first radial directions on the surface, and wherein the first radial distance extends from substantially a center of the surface to substantially a periphery of the surface.

Example 18: Wafer chuck assembly of Example 16, wherein second individual ones of the plurality of mesas are second line mesas that are distributed in a second polar geometry on the surface, wherein individual ones of the second line mesas extend a second radial distance along second radial directions on the surface, and wherein the second radial distance extends between substantially the first radial distance and substantially the periphery of the surface, and wherein the second radial distance is less than the first radial distance

Example 19: Wafer chuck assembly of Example 18, wherein the third line mesas are between the first line mesas and the second line mesas.

Example 20: Wafer chuck assembly of Example 19, wherein the individual ones of the first line mesas are separated from one another by a first angle, wherein individual ones of the second line mesas are separated from one another by a second angle, and wherein individual ones of the third line mesas are separated from one another by a third angle.

Example 21: Wafer chuck assembly of Example 20, wherein the first angle is substantially equal to the second angle, and wherein the second angle is substantially equal to the third angle

Example 22: Wafer chuck assembly of Example 1, wherein a first plurality of mesas comprises a first subset of the plurality of mesas, wherein individual ones of the first plurality of mesas comprise a first sidewall and a second sidewall, wherein the first sidewall extends along a first radial direction on the surface, wherein the second sidewall extends along a second radial direction on the surface, and wherein the first sidewall and the second sidewall extend between a center of the surface to a first radial distance.

Example 23: Wafer chuck assembly of Example 22, wherein a second plurality of mesas comprises a second subset of the plurality of mesas, wherein individual ones of the second plurality of mesas comprise a third sidewall and a fourth sidewall, wherein the third sidewall extends along a third radial direction on the surface, wherein the fourth sidewall extends along a fourth radial direction on the surface, and wherein the third sidewall and the fourth sidewall extend between the first radial distance and a second radial distance.

Example 24: Wafer chuck assembly of Example 23, wherein a third plurality of mesas comprises a third subset of the plurality of mesas, wherein individual ones of the third plurality of mesas comprise a fifth sidewall and a sixth sidewall, wherein the fifth sidewall extends along a fifth radial direction on the surface, wherein the sixth sidewall extends along a sixth radial direction on the surface, and wherein the fifth sidewall and the sixth sidewall extend between the second radial distance and a third radial distance.

Example 25: Wafer chuck assembly of Example 24, wherein a fourth plurality of mesas comprises a fourth subset of the plurality of mesas, wherein: a first individual ones of the fourth subset of mesas comprising: a seventh sidewall that extends along a seventh radial direction; and an eighth sidewall that extends along a first non-diametric chord of the surface, wherein the first non-diametric chord extends at a first oblique angle relative to the seventh radial direction, and wherein the seventh and eighth sidewalls extend between the third radial distance and a fourth radial distance; and a second individual ones of the fourth subset of mesas comprise: a ninth sidewall that extends along an eighth radial direction; and a tenth sidewall that extends along a second non-diametric chord of the surface, wherein the second non-diametric chord extends at a second oblique angle relative to the ninth radial direction, and wherein the ninth and tenth sidewalls extend between the third radial distance and the fourth radial distance; and a third individual ones of the fourth subset of mesas between the first individual ones and the second individual ones of mesas, wherein the third individual ones of the fourth subset of mesas comprise: an eleventh sidewall, wherein the eleventh sidewall is adjacent and parallel to the eighth sidewall; and a twelfth sidewall, wherein the twelfth sidewall is adjacent and parallel to the tenth sidewall, wherein the eleventh sidewall and twelfth sidewall intersect at the third radius and extend to the fourth radius.

Example 26: A wafer processing apparatus, comprising: a wafer processing chamber comprising a wafer chuck assembly, the wafer chuck assembly comprising: a wafer chuck comprising wafer chuck surface having a substantially circular geometry, the wafer chuck surface having a first area; and a plurality of mesas distributed over the wafer chuck surface, wherein individual ones of the plurality of mesas extend a height above the wafer chuck surface, and wherein the plurality of mesas comprises a second area that is at least about a threshold percentage of the first area.

Example 27: Wafer processing apparatus of Example 26, wherein the wafer chuck comprises one or more electrodes operable to electrostatically clamp a wafer substrate to the wafer chuck.

Example 28: Wafer processing apparatus of Example 26, wherein the wafer chuck comprises one or more vacuum ports operable to vacuum clamp a wafer substrate to the wafer chuck.

Example 29: A method for using a wafer processing apparatus, the method comprising: mounting a wafer substrate on a wafer chuck comprising a wafer chuck surface comprising a substantially circular geometry, wherein the wafer chuck surface has a first area and a plurality of mesas distributed over the wafer chuck surface, wherein the plurality of mesas has a second area that is at least about a threshold percentage of the first area; and clamping the wafer substrate to the wafer chuck surface, wherein individual ones of the plurality of mesas contact at least the threshold percentage of a surface of the wafer such that pressure over the individual ones of the mesas from the clamped wafer substrate is below a threshold pressure.

Example 30: Method of Example 29, wherein the threshold percentage of the first area of the wafer chuck surface is between 3% and 90%.

Example 31: Method of Example 29, wherein clamping the wafer substrate to the wafer chuck surface comprises electrostatically clamping the wafer substrate to the wafer chuck surface.

Example 32: Method of Example 29, wherein clamping the wafer substrate to the wafer chuck surface comprises vacuum clamping the wafer substrate to the wafer chuck surface.

1. A wafer chuck assembly, comprising:
a wafer chuck comprising a surface having a substantially circular geometry, the surface having a center and a first area; and
a plurality of mesas distributed over the surface of the wafer chuck, wherein individual ones of the plurality of mesas extend a height above the surface of the wafer chuck, wherein the individual ones of the plurality of mesas comprise a contact surface, and wherein a second area substantially equals a sum of an area of the contact surface of the individual ones of the plurality of mesas is at least 3% of the first area.

2. The wafer chuck assembly of claim 1, wherein the individual ones of the plurality of mesas comprise at least one leading edge that is rounded or sloped.

3. The wafer chuck assembly of claim 1, wherein the second area is between 3% and 90% of the first area, and wherein the height is between 0.01 mm and 0.25 mm.

4. (canceled)

5. The wafer chuck assembly of claim 1, wherein the individual ones of the plurality of mesas comprise a substantially circular or polygonal cross section.

6. The wafer chuck assembly of claim 5, wherein the individual ones of the plurality of mesas have a substantially equal diameter.

7. The wafer chuck assembly of claim 5, wherein a diameter of the individual ones of the plurality of mesas increases with an increase in radial distance along the surface.

8. The wafer chuck assembly of claim 7, wherein the individual ones of the plurality of mesas comprise a substantially polygonal plan view cross section, and wherein the individual ones of the plurality of mesas comprise substantially equal peripheral dimensions, and wherein the substantially polygonal plan view cross section is substantially hexagonal.

9. (canceled)

10. The wafer chuck assembly of claim 8, wherein the individual ones of the plurality of mesas are arranged in a close-packed distribution over the surface, and wherein adjacent individual ones of the plurality of mesas have a substantially equal pitch between the adjacent individual ones of the plurality of mesas.

11. The wafer chuck assembly of claim 10, wherein the adjacent individual ones of the plurality of mesas have a pitch that increases with the increase in the radial distance along the surface, wherein a radial distribution of a number of individual ones of the plurality of mesas per unit area decreases from the center to a periphery of the surface.

12. (canceled)

13. The wafer chuck assembly of claim 10, wherein the adjacent individual ones of the plurality of mesas have a pitch that decreases with the increase in the radial distance along the surface, and wherein a radial distribution of a number of individual ones per unit area of surface increases from the center to a periphery of the surface.

14. (canceled)

15. The wafer chuck assembly of claim 1, wherein the individual ones of the plurality of mesas comprise a wedge, wherein the wedge comprises a first sidewall that extends from a central region of the surface to a periphery of the surface and a second sidewall that extends from the central region to the periphery of the surface, and wherein the first sidewall of a first individual one of the plurality of mesas is adjacent to the second sidewall of a second individual one of the plurality of mesas.

16. The wafer chuck assembly of claim 1, wherein first individual ones of the plurality of mesas are first line mesas that are distributed in a first polar geometry on the surface, wherein individual ones of the first line mesas extend a first radial distance along first radial directions on the surface, and wherein the first radial distance extends from substantially a center of the surface to substantially a periphery of the surface.

17. The wafer chuck assembly of claim 16, wherein second individual ones of the plurality of mesas are second line mesas that are distributed in a second polar geometry on the surface, wherein individual ones of the second line mesas extend a second radial distance along second radial directions on the surface, and wherein the second radial distance extends between substantially the first radial distance and substantially the periphery of the surface, and wherein the second radial distance is less than the first radial distance.

18. The wafer chuck assembly of claim 17, wherein third individual ones of the plurality of mesas are third line mesas that are distributed in a third polar geometry on the surface, wherein individual ones of the third line mesas extend a third radial distance along third radial directions on the surface, wherein the third radial distance extends between substantially the second radial distance and substantially the periphery of the surface, wherein the third radial distance is less than the first radial distance and the second radial distance, and wherein the third line mesas are between the first line mesas and the second line mesas.

19. (canceled)

20. The wafer chuck assembly of claim 18, wherein the individual ones of the first line mesas are separated from one another by a first angle, wherein the individual ones of the second line mesas are separated from one another by a second angle, and wherein the individual ones of the third line mesas are separated from one another by a third angle, wherein the first angle is substantially equal to the second angle, and wherein the second angle is substantially equal to the third angle.

21. (canceled)

22. The wafer chuck assembly of claim 1, wherein a first plurality of mesas comprises a first subset of the plurality of mesas, wherein individual ones of the first plurality of mesas comprise a first sidewall and a second sidewall, wherein the first sidewall extends along a first radial direction on the surface, wherein the second sidewall extends along a second radial direction on the surface, and wherein the first sidewall and the second sidewall extend between a center of the surface to a first radial distance.

23. The wafer chuck assembly of claim 22, wherein a second plurality of mesas comprises a second subset of the plurality of mesas, wherein individual ones of the second plurality of mesas comprise a third sidewall and a fourth sidewall, wherein the third sidewall extends along a third radial direction on the surface, wherein the fourth sidewall extends along a fourth radial direction on the surface, and wherein the third sidewall and the fourth sidewall extend between the first radial distance and a second radial distance.

24. The wafer chuck assembly of claim 23, wherein a third plurality of mesas comprises a third subset of the plurality of mesas, wherein individual ones of the third plurality of mesas comprise a fifth sidewall and a sixth sidewall, wherein the fifth sidewall extends along a fifth radial direction on the surface, wherein the sixth sidewall extends along a sixth radial direction on the surface, and wherein the fifth sidewall and the sixth sidewall extend between the second radial distance and a third radial distance.

25. The wafer chuck assembly of claim 24, wherein a fourth plurality of mesas comprises a fourth subset of the plurality of mesas, wherein:
a first individual ones of the fourth subset of the plurality of mesas comprising:
a seventh sidewall that extends along a seventh radial direction; and
an eighth sidewall that extends along a first non-diametric chord of the surface, wherein the first non-diametric chord extends at a first oblique angle relative to the seventh radial direction, and wherein the seventh sidewall and the eighth sidewall extend between the third radial distance and a fourth radial distance;
a second individual ones of the fourth subset of the plurality of mesas comprising:
a ninth sidewall that extends along an eighth radial direction; and
a tenth sidewall that extends along a second non-diametric chord of the surface, wherein the second non-diametric chord extends at a second oblique angle relative to the eighth radial direction, and wherein the ninth sidewall and the tenth sidewall extend between the third radial distance and the fourth radial distance; and
a third individual ones of the fourth subset of the plurality of mesas between the first individual ones and the second individual ones of mesas, wherein the third individual ones of the fourth subset of the plurality of mesas comprise:
an eleventh sidewall, wherein the eleventh sidewall is adjacent and parallel to the eighth sidewall; and
a twelfth sidewall, wherein the twelfth sidewall is adjacent and parallel to the tenth sidewall, wherein the eleventh sidewall and the twelfth sidewall intersect at the third radial distance and extend to the fourth radial distance.

26. A wafer processing apparatus, comprising:
a wafer processing chamber comprising a wafer chuck assembly, the wafer chuck assembly comprising:
a wafer chuck comprising wafer chuck surface having a substantially circular geometry, the wafer chuck surface having a first area; and
a plurality of mesas distributed over the wafer chuck surface, wherein individual ones of the plurality of mesas extend a height above the wafer chuck surface, and wherein the plurality of mesas comprises a second area that is at least about a threshold percentage of the first area.

27. The wafer processing apparatus of claim 26, wherein the wafer chuck comprises one or more electrodes operable to electrostatically clamp a wafer substrate to the wafer chuck.

28. The wafer processing apparatus of claim 26, wherein the wafer chuck comprises one or more vacuum ports operable to vacuum clamp a wafer substrate to the wafer chuck.

29. A method for using a wafer processing apparatus, the method comprising:
mounting a wafer substrate on a wafer chuck comprising a wafer chuck surface comprising a substantially circular geometry, wherein the wafer chuck surface has a first area and a plurality of mesas distributed over the wafer chuck surface, wherein the plurality of mesas has a second area that is at least about a threshold percentage of the first area; and
clamping the wafer substrate to the wafer chuck surface, wherein individual ones of the plurality of mesas contact at least the threshold percentage of a surface of the wafer substrate such that pressure over the individual ones of the plurality of mesas from the wafer substrate, that is clamped, is below a threshold pressure.

30. The method of claim 29, wherein the threshold percentage of the first area of the wafer chuck surface is between 3% and 90%.

31. The method of claim 29, wherein clamping the wafer substrate to the wafer chuck surface comprises electrostatically clamping the wafer substrate to the wafer chuck surface or wherein clamping the wafer substrate to the wafer chuck surface comprises vacuum clamping the wafer substrate to the wafer chuck surface.

32. (canceled)
